(19) United States
(12) Patent Application Publication
(10) Pub. No.: US 2008/0308412 A1
(43) Pub. Date: Dec. 18, 2008

(54) MULTITARGET SPUTTER SOURCE AND METHOD FOR THE DEPOSITION OF MULTI-LAYERS

(75) Inventor: Hartmut Rohrmann, Schriesheim (DE)

Correspondence Address: PEARNE & GORDON LLP, 1801 EAST 9TH STREET, SUITE 1200, CLEVELAND, OH, 44114-3108, US

(73) Assignee: OC OERLIKON BALZERS AG, Balzers (LI)

(21) Appl. No.: 12/139,096

(22) Filed: Jun. 13, 2008

Related U.S. Application Data
(60) Provisional application No. 60/944,118, filed on Jun. 15, 2007.

(51) Int. Cl. C23C 14/35; C23C 14/34

(52) U.S. Cl. 204/192.15; 204/298.12

(57) ABSTRACT

Apparatus and methods for sputtering are provided, which are useful for sputtering high magnetization saturation materials. In one embodiment, a plurality of sputtering target arrangements are arranged concentrically, wherein independent magnetic fields can be generated at least partially above the respective target arrangements. One or several target arrangements can include respective upper and lower parts that are spaced from one another but arranged in essentially parallel planes. Methods include co-sputtering from multiple target arrangements to produce sputtered alloy layers on a substrate, as well as alternately sputtering from different target arrangements to produce a plurality of sputtered layers on the substrate.

This application claims the benefit of U.S. provisional patent application Ser. No. 60/944,118 filed Jun. 15, 2007, the contents of which are incorporated herein by reference.

### FIELD OF THE INVENTION

This invention relates to multitarget sputter sources for materials with high saturation magnetization and a method for the deposition of multilayers and further to a method for Co-Sputtering of alloys incorporating materials of high saturation magnetization.

### BACKGROUND OF THE INVENTION

Multi-target sputter sources are well proven for the deposition of multi-layers and special alloys in hard disk media. EP 0 162 643 shows the basic principle of such a sputter source comprising concentric annular targets with independent magnetic poles and independent plasma power sources. FIG. 1 of this present application shows the Oerlikon/Unaxis Triatron sputter source 15 with three concentric targets 10, 11, 12 with respective magnetic means (permanent magnets arranged beneath the target). Usually a separate power supply for each target, typically DC power supply, is being used. In the Triatron design there is no anode arranged between the concentric targets 10-12 and the spacing between the targets is reduced to the spacing required to avoid parasitic plasma between the targets (dark space). A shielding 14 is provided to collect material not reaching the substrate 13. The substrate is arranged in a plane, distant but essentially in parallel to the plane of the unused sputter surfaces. Here the substrate is shown with a center, hole, as it is e. g. common for hard disk substrates. The diameter of such substrates is usually varying from 20 to 100 mm. In the arrangement shown the outer diameter of annular target 10 is 165 mm, of target 11 121 mm, target, 12 72 mm. The expert will vary the diameter according to the needs of the films/layers to be sputtered, including the teachings described in U.S. Pat. No. 6,579,424, which is incorporated herein by reference.

In a typical application the outermost target 10 and the innermost target 12 consist of cobalt Co, target 11 of Palladium Pd. The thickness of the target varies from 2 mm to 8 mm. The target-substrate distance is typically 50 mm.

This lay-out works well for nonmagnetic targets and for targets of low magnetization, but has very limited performance for high magnetization target materials which are frequently used in the production of magnetic hard disks. The problem of sputtering high magnetization materials is that the magnetic field produced by an array of magnets behind the target does not penetrate the magnetic target sufficiently. Since a magnetic field projecting above the surface of a target is a prerequesite for the occurrence of the magnetron sputter effect, it is clear that high magnetization targets cannot easily be applied in standard magnetron cathodes, since the width of the eroded area tends to be too small (pinging effect).

Several possibilities to sputter high magnetization material are known in the art: One comprises to choose stronger magnets to magnetically (over-) saturate the target and/or to choose thin targets of a few Millimeters of material.

A further known technology to sputter high magnetization material is a target arrangement 40 with trenches and bores, shown in FIG. 5. A target 46 of high magnetization material is placed on magnets 42, 43. On the backside a yoke 41 may be used. The target 46 will guide most, if not all of the magnetic flux lines. By applying a trench 44 or a bore 45 the magnetic flux lines are forced to bridge a gap. In such areas a plasma can ignite and a magnetron sputtering effect can occur. Typically, the trenches will have a width of 0.5 to 1.5 mm. A target thickness of 20 mm has been used successfully.

Another known technology for sputtering high magnetization materials is the so called roof target arrangement as shown in U.S. Pat. No. 4,572,776 or U.S. Pat. No. 4,601,806 respectively. FIGS. 4a & b illustrate the principle. In this arrangement the target material is divided into at least two parts, with one part arranged partially in a plane essentially parallel to and above the surface of the other part. FIG. 4a illustrates this with the cross-section of a three-part-design; target 21 being arranged in a first, “lower” plane and targets 20, 22 arranged in a second, “upper” plane. FIG. 6 illustrates a topview on said roof target arrangement; it is clear, that such a design is applicable to an elongated target configuration, comprising sections I, II and III as well as to a circular configuration composed from sections I and III only. In a basic arrangement the middle part 22 could be omitted with the target part 21 being then a continuous plate. However, since the transitions between the target parts are also the active, plasma-exposed ones, omitting such further target part results in a loss of active area.

FIG. 4a illustrates a cross section through a target arrangement with a central axis A.

FIG. 4b shows with more detail the magnetic properties for one half of said target arrangement. In this arrangement the magnetic field is produced by permanent magnets 23, 24, 25. For material with high magnetization saturation an undivided target will act as a shunt for the magnet field lines, i. e. figuratively there will be not sufficient field lines available above the target surface in order to allow the formation of a tunnel-like magnetic field which is again the prerequisite for the closed plasma loop of the magnetron effect. By dividing the target 20, 21, 22 the magnetic field lines generated by magnets 23, 24, 25 are forced to bridge the gaps as indicated in FIG. 4b, so that in the regions marked F₂ two tunnel-like magnetic fields occur. Here the magnetic field extends from the upper target part 20, 22 to the lower target part 21 and the magnetic target material itself is used as a magnetic flux guide resulting in sufficiently strong magnetic fields above the target arrangement. With the help of this magnetic field the erosion area is widened compared to a conventional target arrangement with a flat target and permanent magnets arranged behind the target. Additionally, the target thickness of the high magnetization material is not limited by the available strength of the permanent magnets. Further, a certain focusing effect can be observed, i. e. the sputtered material has a preferred direction due to the step-like design of the sputter region.

It has to be noted, that the arrangement shown in U.S. Pat. No. 4,572,776 or U.S. Pat. No. 4,601,806 respectively use a single power source and the same material for all target parts.

Materials with high magnetization are materials with a saturation magnetization (4π Ms) of more than 8000 Gauss (in cgs-units).

Disadvantages of Existing Triatron Design:
For materials with high magnetization only very thin targets can be used and the target utilization is low due to the fact that the target is eroded only on a small area (pinging effect).
RF sputtering of the high magnetization material is in principle possible with the existing Triatron design. However, the maximum possible sputter rate is quite low and there is a large power directed to the substrate causing excessive heating of the substrate and deterioration of the film properties due to the fact that with RF sputtering the volume of the sputtering plasma extends towards the substrate.

Disadvantage of the Roof Target Technology:
Only a single target material arrangement is known in the prior art, which does not allow to produce multi layers or alloying of materials in the deposited film by co-sputtering.
Furthermore, with a target arrangement as known in the art (FIG. 4a, b) there are two areas on the target with respective plasmas and it is very difficult to control the relative sputter powers in the two respective areas.

Disadvantage of the Trench & Bore Technology:
Again, only a single material can be used in such an arrangement and does provide for the possibility to produce multi layers or alloying of materials in the deposited film by co-sputtering. The fabrication process of such targets is elaborate and expensive, especially if many bores and/or trenches are necessary.

### SUMMARY OF THE INVENTION

The solution according to the invention is directed to combining the advantages from the technologies described above and at the same time directed to avoiding the individual, known disadvantages of said sources. Moreover it has been found that by carefully choosing process parameters and material's choice further advantages can be realized.

An exemplary sputter source as disclosed herein includes a first target arrangement and a second target arrangement. The second target arrangement is disposed around the first target arrangement when viewed from above. At least one of the target arrangements has an upper part and a lower part, wherein the upper part is arranged in a plane spaced apart from and essentially parallel to the plane of the lower part. The upper part protrudes partially over the lower part. The sputter source also includes means for generating magnetic fields. The magnetic-field generating means is operable to separately generate first and second individually-controllable magnetic fields, respectively, at least partially above the first and second target arrangements.

A method of sputtering is also provided, which includes providing a sputter source having a first target arrangement and a second target arrangement, wherein the second target arrangement is disposed around the first target arrangement when viewed from above, wherein at least one of the target arrangements has an upper part and a lower part, wherein the upper part is arranged in a plane spaced apart from and essentially parallel to the plane of the lower part, and wherein the upper part protrudes partially over the lower part; providing a substrate arranged above and spaced from the target arrangements; generating a first magnetic field at least partially above the first target arrangement to thereby sputter material from the first target arrangement onto the substrate; and generating a second magnetic field at least partially above the second target arrangement to thereby sputter material from the second target arrangement onto the substrate; wherein the first magnetic field is generated and controlled independently of the second magnetic field.

A target arrangement as described herein refers to a target surface from which sputter material is drawn during a sputtering operation as known in the art, where selectively a sputtering plasma can be ignited during operation. The addressed target surface needs not to form an uninterrupted plane, but may comprise steps, trenches, bores or other gaps.

A general embodiment of the invention can be described as a sputter coating apparatus with at least two target arrangements (1a/b, 2, 3a/b); a first target arrangement and a second target arrangement completely surrounding said first target arrangement; means for generating a magnetic field at least partially above each of said target arrangements and individually controllable power sources allocated to each of said target arrangements. In a preferred embodiment of said general embodiment at least one of said target arrangements comprises a first (e. g. upper 1a, 3a) and a second (e. g. lower 1b, 3b) part, said first part being arranged in a plane spaced apart from and essentially parallel to the plane of said second part and said first part protruding partially over said second part. In another preferred embodiment of said general embodiment at least one of said target arrangement comprises trenches, bores or other gaps.

In a further embodiment a third target arrangement completely surrounding said second and first target arrangement is provided for.

In further preferred embodiments said targets may be construed to feature an annular, concentric design or an extended design as shown in FIG. 6. Materials of said target arrangements may vary with materials of high magnetization saturation being arranged preferably in target arrangements with lower/upper part design.

Such sputter coating apparatus may be used for methods for coating substrates with films of materials of high magnetization saturation; either alone or in combination or alternation with other materials in order to form alloyed films or alternating films (layer systems) on said substrates. With said inventive apparatus being able to provide different materials in one source there is no need to transport a substrate between different process stations being individually equipped with sources dedicated for one material or material alloy.

### BRIEF DESCRIPTION OF THE DRAWINGS

All of the following figures are schematic and illustrative in nature.

FIG. 1 shows a cross-section of a conventional multi-target source arrangement for magnetron sputtering.

FIG. 2 shows a cross-section of a multi-target source arrangement for magnetron sputtering according to an exemplary embodiment of the invention.

FIG. 3 shows a cross-section as in FIG. 2, wherein the sputtering targets have been eroded through sputtering to near the end of their lives.

FIG. 4a shows a conventional roof-target sputtering arrangement.

FIG. 4b illustrates magnetic field lines associated with the operation of the roof-target sputtering system illustrated in FIG. 4a.

FIG. 5 illustrates a sputter-target arrangement including bores and trenches in the sputter targets

FIG. 6 is a plan view of a multi-source sputter target arrangement in a ‘racetrack’ configuration, wherein the sputter targets have been elongated linearly relative to an axis of symmetry.

FIG. 7a shows a cross-section of a multi-target source arrangement for magnetron sputtering according to a further exemplary embodiment of the invention.

FIG. 7b shows a cross-section as in FIG. 7a, wherein the sputtering targets have been eroded through sputtering to near the end of their lives.

FIG. 7c shows a cross-section of a multi-target source arrangement for magnetron sputtering according to yet a further exemplary embodiment of the invention.

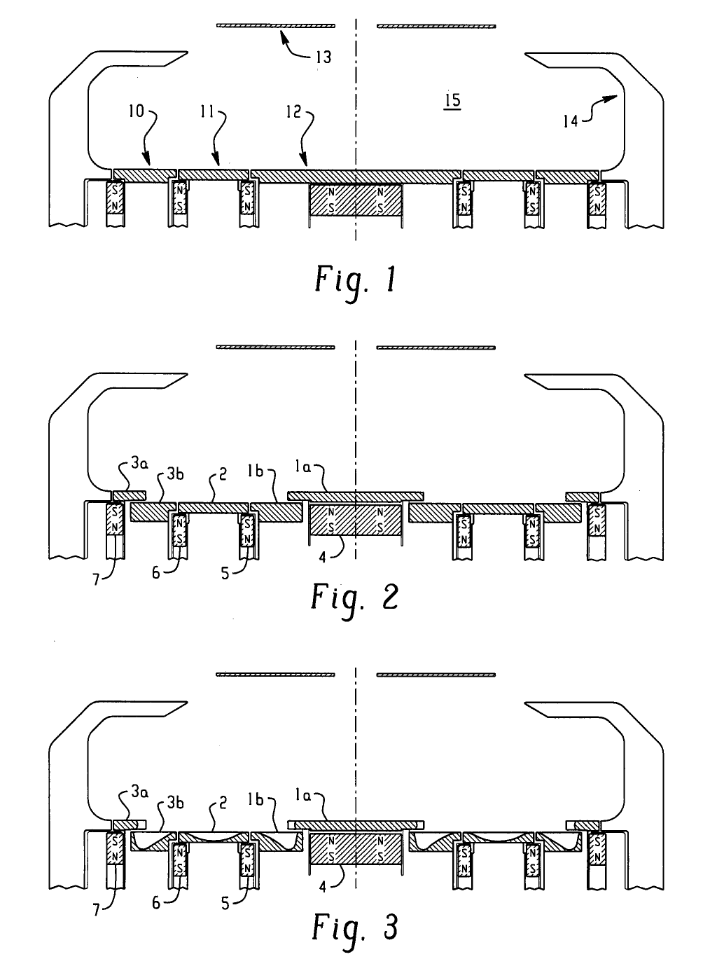

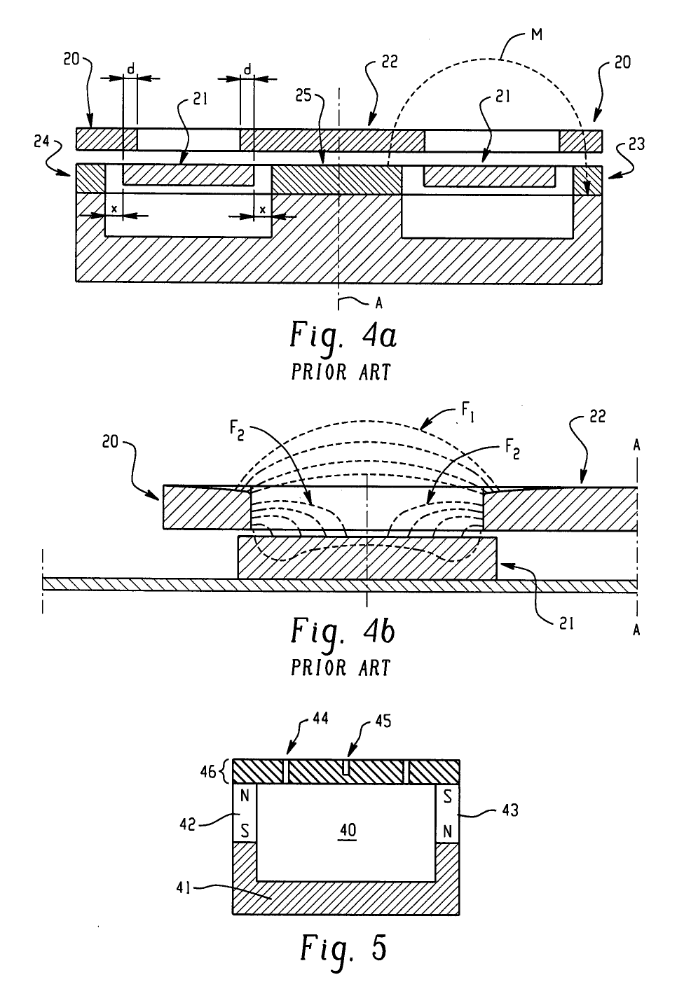

### DETAILED DESCRIPTION OF PREFERRED EMBODIMENTS

The solution will now be described, with the aid of the figures. Customary accessories like vacuum pumps, electric connectors, cooling systems, gas inlets and alike have been omitted to facilitate understanding. It is understood that a man skilled in the art will add such equipment based on his knowledge without further inventive effort. Such an inventive sputter source will be assembled in a vacuum vessel with means to provide for a sufficient vacuum and supply lines for a working gas for the plasma process such as Argon or Krypton under conditions to be adjusted to the respective pressure regime and flow rate. Commonly used pressure ranges from 6×10⁻⁴ to 6×10⁻² hPa (mbar).

In FIG. 2 the inner target arrangement 1a/1b and the outer target arrangement 3a/3b are construed to comprise materials with high magnetization. These two target arrangements are divided into an upper (1a and 3a) and a lower part (1b and 3b) in a step-like arrangement. Upper and lower parts do not touch, the vertical distance between them is chosen as a compromise between the needs of guiding the magnetic field and avoiding parasitic plasma igniting in the gap. This distance will normally be between 0.5 and 6 mm, preferably between 1-1.5 mm, depending on the electric and magnetic properties. The middle target arrangement 2 (ringshaped) is shown as comprising nonmagnetic or low-magnetization material. The arrangement of permanent magnets consists of four concentric rings 4-7 with a magnetic polarity which is alternating from one ring to the next ring. The magnetron field for the inner target 1a/1b is produced by the permanent magnet rings 4 and 5. The magnetron field for the middle target 2 is produced by the permanent magnet rings 5 and 6. The magnetron field for the outer target 3a/3b is produced by the permanent magnet rings 6 and 7. The strength of said magnets is chosen according to the specific requirements of the sputtering process and takes into account the material to be sputtered.

This arrangement utilizes the roof target effect for the two pairs of targets 1a/1b and 3a/3b, respectively. Due to this effect high magnetization materials can be used for the targets 1a/1b and 3a/3b and the eroded area on these targets has a large width as indicated in the graph by the curves 8 and 9, respectively. Moreover the a. m. focus effect can be utilized to improve the deposition homogeneity in the substrate. Due to the fact that the sputter voltage can be applied independently to the target arrangements 1a/1b and 3a/3b, respectively, the sputter power on these two areas can easily be controlled independently and the areas can be sputtered independently.

The target 2 may also be used as an independent sputter source and by applying a power to this sputter target 2 the advantages of the Triatron design can be utilized for high magnetization materials in combination with non magnetic/low magnetization materials. There are several modes of operation for such a source according to FIGS. 2, 3:
In one suggested sputter mode the targets 1a/1b and 3a/3b are made of the same high magnetization material and are sputtered simultaneously to form a first film while the target 2 is not sputtered. A second film is then formed by sputtering target 2 while the targets 1a/1b and 3a/3b are not sputtered. A multi-layer structure of thin films can be formed by repeating this sputter sequence. The sputter powers on target 1a/1b and target 3a/3b are typically tuned to reach an optimal uniformity of the sputtered high magnetization material on the substrate.
In a variation of this first sputter mode, the sputter power on target 2 is reduced to a very small level (typically in the range 5-20 W) while sputtering the targets 1a/1b and 3a/3b with higher power and, in the opposite logic, sputtering the targets 1a/1b and 3a/3b with a very small power (5-20 W each) while sputtering the target 2 with higher power. This mode is used to prevent deposition of the high magnetisation material from target 1a/1b and 3a/3b on target 2, and, in the same way, deposition of the non magnetic/low magnetization material from target 2 on target 1a/1b and 3a/3b during sputtering the other material, respectively. With this sputter mode, the cross contamination of the different materials is reduced.
In another suggested sputter mode all targets are sputtered simultaneously to form an alloyed film on the substrate. The composition of the alloyed film is adjusted by adjusting the sputter powers on the targets 1a/1b, 2 and 3a/3b, respectively.
It is possible to operate the targets 1a/1b & 3a/3b with a DC power supplies (independently) and target 2 with DC or RF power supply. Other combinations of power supplies may be used. The power ratios for the supplies will be adjusted according to the needs of the sputtering process.
In case reactive sputtering should be necessary, the inventive sputter apparatus may be complemented by respective gas inlets in order to allow reactive sputtering.
Other sputter modes with sequences of alloying and deposition of thin film stacks with varying thicknesses can be realized straightforwardly.

The described inventive sputtering apparatus allows sputtering of a choice of materials nowadays used in modern Hard Disk layer design:

| Target 3a, 3b | Target 2 | Target 1a, 1b |
|---|---|---|
| Fe | Pt | Fe |
| CoCrPt(B) | Ru | CoCrPt(B) |
| CoCrPt(B) | SiO₂ | CoCrPt(B) |
| CoFe | X | CoFe |
| CoZr | X | CoZr |
| FeTb | X | FeTb |
| FeCoTbGd | X | FeCoTbGd |

X = Pt, Pd, Ru or alloys thereof.

The examples given are exemplary and not exhaustive.

It is further possible to equip all three target arrangements with targets comprising the same materials, but different shares (concentrations). Preferably expensive materials like Pt, Pd, Ru will be used for target 2.

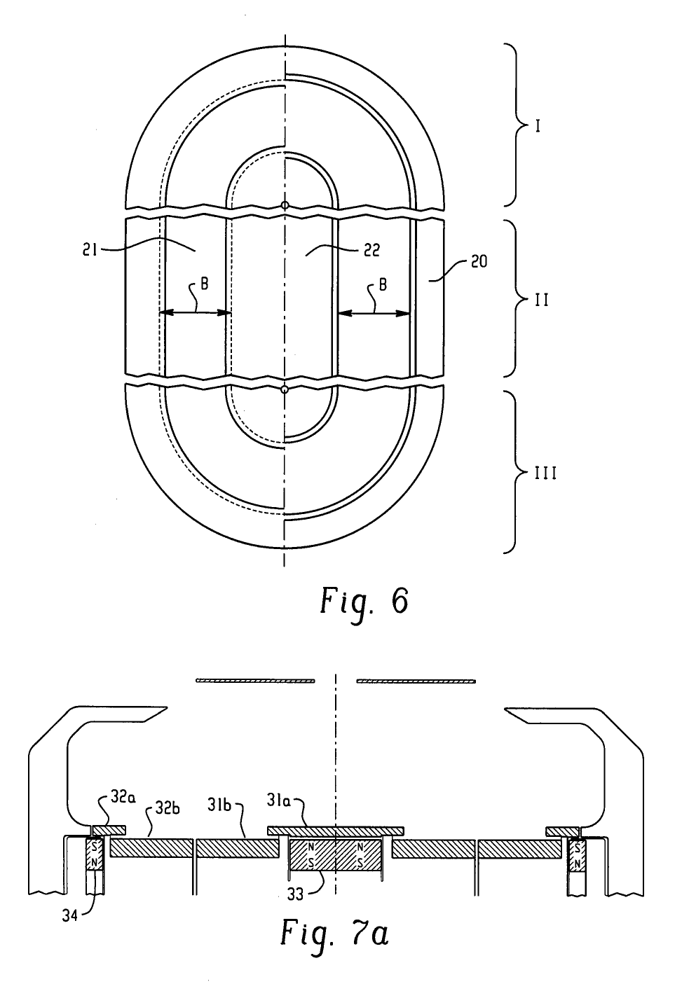

For hard disk applications the sputter source preferably has circular shape with a concentric arrangement of targets and permanent magnets. However, a linearly extended sputter source as described for example in FIG. 6 is also possible with the current invention.

With a source and methods of operation according to the invention it is possible to create layer systems for soft magnetic underlayers in Hard Disks, e. g. FeCo, FeCoB or CoZrX (X═Ta, Nb). The subsequent use a further source according to the invention equipped with another set of target materials will allow to create CoCrPt+SiO₂ layers by the a. m. co-sputtering method.

Even the so called L10 phase can be realised based on a layer system Fe(Co)—Pt—Fe(Co)—Pt . . . with a sputter coating apparatus according to the invention.

FIG. 3 shows said inventive embodiment as discussed for FIG. 2 with eroded target parts.

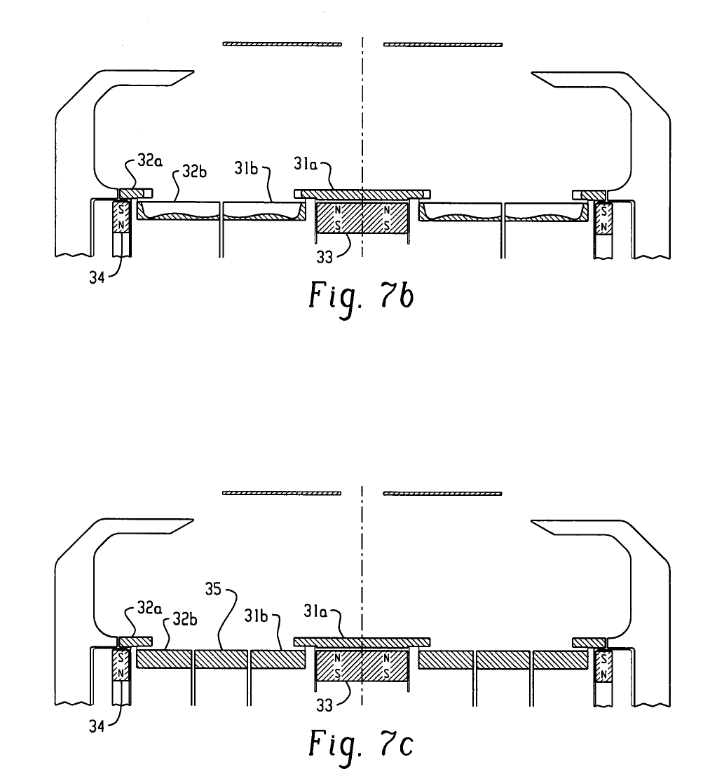

FIG. 7a shows an embodiment with a step-like target arrangement 32a/32b and 31a/31b plus an arrangement with a central trench between 32b and 31b. The magnetic flux can be provided by two sets of magnets 33, 34. The high magnetization material of target parts 31a/b, 32a/b will guide the magnetic flus respectively. The individual power distribution to said target arrangements allows the control of the sputter areas between 32a & b, 32b & 31b, 31b & 31a. Again, this layout may be combined with further (concentric) target arrangements exhibiting roof-target technology/bore-trench technology or standard sputtering.

FIG. 7b shows the embodiment of FIG. 7a with eroded target parts.

FIG. 7c exhibits another variant of FIG. 7a with a further trench, creating an additional target arrangement. Again, target part 35 with individual power attribution will allow the control of the plasma regions.

While the invention has been described with respect to preferred embodiments, it will be understood that the invention is not to be limited thereby. Numerous additional embodiments and features will be readily apparent to the person having ordinary skill in the art based on reading the present disclosure, which fall within the spirit and the scope of the present invention as set forth in the appended claims.

What is claimed is:

1. A sputter source comprising:
a first target arrangement and a second target arrangement, said second target arrangement being disposed around said first target arrangement when viewed from above, at least one of said target arrangements comprising an upper part and a lower part, said upper part being arranged in a plane spaced apart from and essentially parallel to the plane of said lower part, said upper part protruding partially over said lower part; and
means for generating magnetic fields, said magnetic-field generating means being operable to separately generate first and second individually-controllable magnetic fields, respectively, at least partially above said first and second target arrangements.

2. The sputter source of claim 1, said magnetic-field generating means comprising separate power sources allocated to generate said individually-controllable magnetic fields.

3. The sputter source of claim 1, at least one of said target arrangement comprising trenches, bores or other gaps.

4. The sputter source of claim 1, further comprising a third target arrangement disposed around said second target arrangement when viewed from above.

5. The sputter source of claim 4, said magnetic-field generating means being operable to separately generate a third individually-controllable magnetic field at least partially above said third target arrangement.

6. The sputter source of claim 4, said first and third target arrangements each comprising respective upper and lower parts, said upper parts being arranged in a common upper plane, said lower parts being arranged in a common lower plane, wherein said upper plane is spaced apart from and essentially parallel to said lower plane.

7. The sputter source of claim 6, said second target arrangement being arranged in said lower plane.

8. The sputter source of claim 1, wherein each of said first and second target arrangements comprises an upper part and a lower part, said upper parts being arranged in a common upper plane and said lower parts being arranged in a common lower plane, wherein said upper plane is spaced apart from and essentially parallel to said lower plane.

9. The sputter source of claim 1, said target arrangements having an annular, concentric design wherein said second target arrangement is arranged concentrically around said first target arrangement when viewed from above.

10. The sputter source of claim 9, said target arrangements being elongated linearly relative to an axis of symmetry.

11. The sputter source of claim 1, at least one of said first and second target arrangements comprising a material exhibiting high magnetization saturation.

12. The sputter source of claim 1, one of said first and second target arrangements comprising a material exhibiting high magnetization saturation and the other said target arrangement comprising a material exhibiting low magnetization saturation.

13. The sputter source of claim 1, said at least one target arrangement having said upper part and said lower part comprising a material exhibiting high magnetization saturation.

14. The sputter source of claim 6, at least one of said first and third target arrangements comprising a material exhibiting high magnetization saturation.

15. A method of sputtering comprising:
providing a sputter source comprising a first target arrangement and a second target arrangement, said second target arrangement being disposed around said first target arrangement when viewed from above, at least one of said target arrangements comprising an upper part and a lower part, said upper part being arranged in a plane spaced apart from and essentially parallel to the plane of said lower part, said upper part protruding partially over said lower part;
providing a substrate arranged above and spaced from said target arrangements;
generating a first magnetic field at least partially above said first target arrangement to thereby sputter material from said first target arrangement onto said substrate; and
generating a second magnetic field at least partially above said second target arrangement to thereby sputter material from said second target arrangement onto said substrate;
wherein said first magnetic field is generated and controlled independently of said second magnetic field.

16. The method of claim 15, each of said first and second magnetic fields being generated from its own independent power source.

17. The method of claim 15, said sputter source further comprising a third target arrangement disposed around said second target arrangement when viewed from above, the method further comprising generating a third magnetic field at least partially above said third target arrangement to thereby sputter material from said second target arrangement onto said substrate, wherein said third magnetic field is generated and controlled independently of each of said first and second magnetic fields.

18. The method of claim 15, at least one of said first and second target arrangements comprising a material exhibiting high magnetization saturation.

19. The method of claim 15, said at least one target arrangement having said upper part and said lower part comprising a material exhibiting high magnetization saturation.

20. The method of claim 15, comprising co-sputtering material from each of said first and second target arrangements onto said substrate to produce an alloy layer comprising material from each of said target arrangements.

21. The method of claim 15, comprising sputtering material from one of said first and second target arrangements onto said substrate and thereafter sputtering material from the other of said first and second target arrangements onto said substrate, thereby providing a plurality of sputtered layers on said substrate comprising discrete layers of material sputtered alternately from said first and second target arrangements.

22. The method of claim 20, comprising generating said first and second magnetic fields simultaneously to achieve said co-sputtering.

23. The method of claim 21, comprising alternately generating said first and second magnetic fields individually to achieve alternate sputtering of material from said first and second target arrangements, respectively, to provide said plurality of sputtered layers.

24. The method of claim 21, comprising:
first generating said first magnetic field at a low level and simultaneously generating said second magnetic field at a level effective to sputter material from said second target arrangement onto said substrate;
thereafter generating said second magnetic field at a low level and simultaneously generating said first magnetic field at a level effective to sputter material from said first target arrangement onto said substrate;
wherein said low-level magnetic fields are effective to inhibit cross-contamination of material between the respective first and second target arrangements.

25. The method of claim 24, one of said first and second target arrangements comprising a material exhibiting high magnetization saturation, and the other of said target arrangements exhibiting low magnetization saturation.
